(19) United States
(12) Patent Application Publication
(10) Pub. No.: US 2018/0087156 A1
(43) Pub. Date: Mar. 29, 2018

(54) Gas Introduction Mechanism and Processing Apparatus

(71) Applicant: TOKYO ELECTRON LIMITED, Tokyo (JP)

(72) Inventors: Kohei FUKUSHIMA, Iwate (JP); Hiromi NITADORI, Iwate (JP)

(21) Appl. No.: 15/715,557

(22) Filed: Sep. 26, 2017

(30) Foreign Application Priority Data
Sep. 27, 2016 (JP) 2016-188311

(51) Int. Cl. C23C 16/455; C23C 16/458

(52) U.S. Cl. CPC C23C 16/45578; C23C 16/4583

(57) ABSTRACT

A gas introduction mechanism includes a manifold disposed in a process vessel and having an injector support part extending vertically along an inner wall surface of the process vessel and having an insertion hole, and a gas introduction part having a gas flow passage which protrudes outward from the injector support part and which communicates with the insertion hole and an outside of the process vessel so that a gas can flow through the insertion hole and the outside of the process vessel, an injector inserted and fitted into the insertion hole to be supported by the insertion hole, and extending linearly entirely within the injector along the inner wall surface and has an opening communicating with the gas flow passage at a position inserted into the insertion hole, and a rotation mechanism connected to a lower end portion of the injector to rotate the injector.

### CROSS-REFERENCE TO RELATED APPLICATION

This application is based upon and claims the benefit of priority from Japanese Patent Application No. 2016-188311, filed on Sep. 27, 2016, the entire contents of which are incorporated herein by reference.

### TECHNICAL FIELD

The present disclosure relates to a gas introduction mechanism and a processing apparatus.

### BACKGROUND

A batch-type substrate processing apparatus capable of performing a film forming process or the like on a plurality of substrates in a process vessel in a state in which the substrates are supported on a substrate support in multiple stages is known.

In this batch-type substrate processing apparatus, a gas flow passage is formed in a sidewall of the process vessel, and a horizontal portion of an L-shaped injector is inserted into a side of the process vessel of the gas flow passage so that the injector is fixed to the process vessel. In a vertical portion of the injector, a plurality of gas ejection ports are formed along a direction (a vertical direction) in which the substrates are stacked.

In the substrate processing apparatus mentioned above, however, since the injector is fixed to the process vessel, the direction in which gas is discharged is constant, making it impossible to sufficiently control the in-plane distribution of characteristics of a film formed on the substrate.

### SUMMARY

The present disclosure provides some embodiments of a gas introduction mechanism capable of controlling an in-plane distribution in a process performed on a substrate.

According to one embodiment of the present disclosure, there is provided a gas introduction mechanism installed in a process vessel to perform a predetermined process on a substrate in the process vessel using a predetermined gas, including: a manifold disposed in a lower end portion of the process vessel, and having an injector support part extending vertically along an inner wall surface of the process vessel and having an insertion hole, and a gas introduction part having a gas flow passage which protrudes outward from the injector support part and which communicates with the insertion hole and an outside of the process vessel so that a gas can flow through the insertion hole and the outside of the process vessel; an injector inserted and fitted into the insertion hole to be supported by the insertion hole, and extending linearly entirely within the injector along the inner wall surface and has an opening communicating with the gas flow passage at a position inserted into the insertion hole; and a rotation mechanism connected to a lower end portion of the injector to rotate the injector.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic diagram of a processing apparatus according to one embodiment of the present disclosure.

FIGS. 2A to 2C are cross sectional views illustrating an injector of the processing apparatus of FIG. 1.

FIGS. 3A and 3B are first views illustrating a gas introduction mechanism of the processing apparatus of FIG. 1.

FIG. 4 is a view illustrating an internal structure of the gas introduction mechanism of FIGS. 3A and 3B.

FIGS. 5A and 5B are second views illustrating a gas introduction mechanism of the processing apparatus of FIG. 1.

FIGS. 6A and 6B are third views illustrating the gas introduction mechanism of the processing apparatus of FIG. 1.

FIG. 7 is a fourth view illustrating the gas introduction mechanism of the processing apparatus of FIG. 1.

FIGS. 8A to 8C are views illustrating a direction of a gas discharged from a gas hole of the injector.

FIG. 9 is a diagram illustrating an in-plane distribution of film thickness of a film formed on a wafer.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments. Furthermore, in the present specification and drawings, substantially the same components will be denoted by the same reference numbers and a redundant description will be omitted.

### (Processing Apparatus)

A processing apparatus according to one embodiment of the present disclosure will be described. In one embodiment, a processing apparatus that performs heat treatment on a substrate will be described as an example, but the processing target and the processing contents are not particularly limited and the present disclosure is applicable to various processing apparatuses that supply a gas into a process vessel and perform the processing.

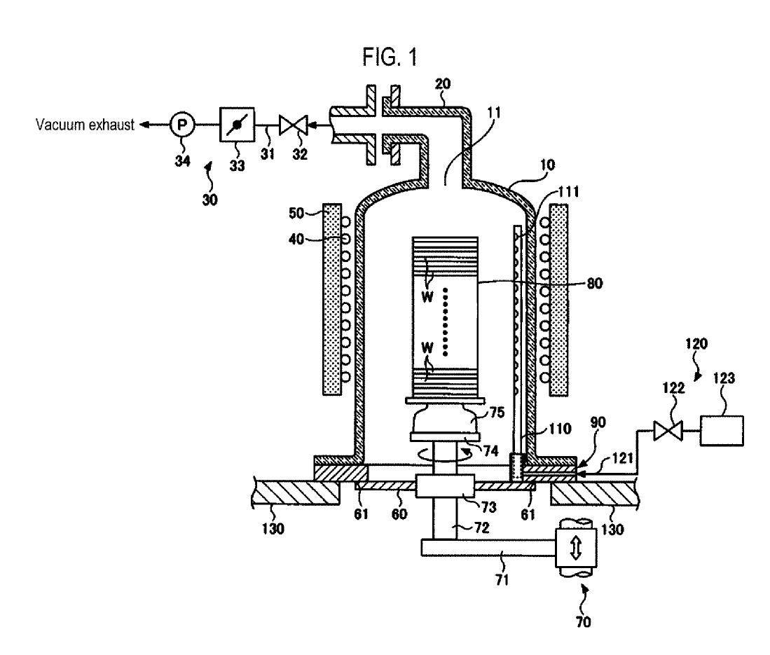

FIG. 1 is a schematic diagram of a processing apparatus according to one embodiment of the present disclosure.

As illustrated in FIG. 1, the processing apparatus has a process vessel 10 that can accommodate a semiconductor wafer (hereinafter, referred to as a “wafer W”). The process vessel 10 is made of quartz having high heat resistance, has a substantially cylindrical shape, and has an exhaust port 11 on its ceiling. The process vessel 10 is formed in a vertical shape extending in a vertical direction. For example, when the diameter of the wafer W to be processed is 300 mm, the diameter of the process vessel 10 is set to fall within a range of about 350 to 450 mm

A gas exhaust port 20 is connected to the exhaust port 11 of the ceiling portion of the process vessel 10. The gas exhaust port 20 is formed of, for example, a quartz tube extending from the exhaust port 11 and bent at right angles in an L shape.

A vacuum exhaust system 30 for exhausting the internal atmosphere of the process vessel 10 is connected to the gas exhaust port 20. Specifically, the vacuum exhaust system 30 has a gas exhaust pipe 31 made of metal, e.g., stainless steel, connected to the gas exhaust port 20. In addition, an opening/closing valve 32, a pressure regulating valve 33 such as a butterfly valve, and a vacuum pump 34 are sequentially installed in the middle of the gas exhaust pipe 31 so as to evacuate the interior of the process vessel 10 while regulating the internal pressure thereof. Furthermore, the inner diameter of the gas exhaust port 20 is set to be equal to the inner diameter of the gas exhaust pipe 31.

A heating means 40 is installed at a side portion of the process vessel 10 to surround the process vessel 10, so that the heating means 40 can heat the wafer W accommodated in the process vessel 10. The heating means 40 is divided into, for example, a plurality of zones, and is constituted by a plurality of heaters (not shown) whose heat generation amounts can be independently controlled from an upper side to a lower side in the vertical direction. The heating means 40 may also be configured by one heater without being divided into a plurality of zones. In addition, a heat insulating material 50 is provided on an outer periphery of the heating means 40 so as to ensure thermal stability.

The lower end portion of the process vessel 10 is opened so that the wafer W can be carried in and out. The lower end opening of the process vessel 10 is configured to be opened and closed by a lid 60.

A wafer boat 80 is provided above the lid 60. The wafer boat 80 is a substrate support for supporting the wafer W, and is configured to support a plurality of wafers W in a vertically spaced state. The number of wafers W supported by the wafer boat 80 is not particularly limited but may be, for example, 50 to 150 wafers.

The wafer boat 80 is mounted on a table 74 via a heat insulating tube 75 made of quartz. The table 74 is supported by an upper end portion of a rotary shaft 72 penetrating the lid 60 that opens and closes the lower end opening of the process vessel 10. For example, a magnetic fluid seal 73 is installed in a portion through which the rotary shaft 72 penetrates to rotatably support the rotary shaft 72 in a hermetically sealed state. In addition, a seal member 61 such as, e.g., an O-ring is installed in a peripheral portion of the lid 60 and the lower end portion of the process vessel 10 so as to maintain the sealing property in the process vessel 10.

The rotary shaft 72 is installed at a leading end of an arm 71 supported by an elevating mechanism 70 such as, e.g., a boat elevator, and is configured to integrally move the wafer boat 80, the lid 60, and the like up and down. Furthermore, the table 74 may also be fixedly installed at the lid 60 side so that the wafers W are processed without rotation of the wafer boat 80.

A manifold 90 having a portion extending along an inner peripheral wall of the process vessel 10 and also having a flange-shaped portion extending radially outward is disposed in the lower end portion of the process vessel 10. A necessary gas is introduced into the process vessel 10 from the lower end portion of the process vessel 10 via the manifold 90. The manifold 90 is configured as a separate part from the process vessel 10 but is integrally formed with the sidewall of the process vessel 10 to constitute a portion of the sidewall of the process vessel 10. A detailed configuration of the manifold 90 will be described herein below.

The manifold 90 supports the injector 110. The injector 110 is a tubular member for supplying a gas into the process vessel 10, and is made of, for example, quartz. The injector 110 is installed to extend in the vertical direction within the process vessel 10. A plurality of gas holes 111 are formed in the injector 110 at predetermined intervals along a longitudinal direction so that the gas can be discharged from the gas holes 111 in the horizontal direction.

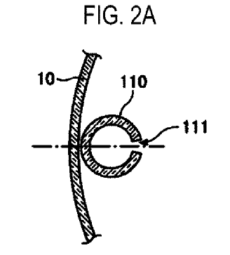

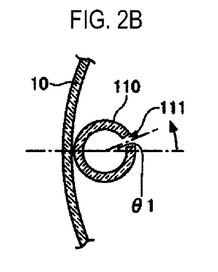

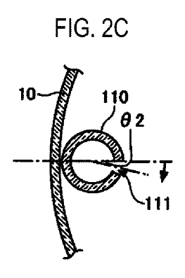

FIGS. 2A to 2C are cross sectional views illustrating the injector of the processing apparatus of FIG. 1. FIG. 2A illustrates a state of the injector 110 at a starting position. FIG. 2B illustrates a state of the injector 110 at a position to which the injector 110 has rotated by a predetermined angle θ1 from the starting position in a leftward direction, and FIG. 2C illustrates a state of the injector 110 at a position to which the injector 110 has rotated by a predetermined angle θ2 from the starting position in a rightward direction.

The injector 110 is connected to a rotation mechanism, which will be described later, and is configured to be rotatable in the leftward direction and the rightward direction according to an operation of the rotation mechanism. Specifically, the injector 110 may be rotatable from the position in which the gas hole 111 is oriented to the center of the process vessel 10 as illustrated in FIG. 2A to the position of the angle θ1 in the leftward direction as illustrated in FIG. 2B. Furthermore, the injector 110 may be rotatable to the position of the angle θ2 in the rightward direction as illustrated in FIG. 2C. Then, by rotating the injector 110 in a state in which a gas is discharged from the gas hole 111 of the injector 110 in a horizontal direction, it is possible to control an in-plane distribution of the process performed on the wafer W.

Referring back to FIG. 1, a gas supply system 120 is connected to the injector 110 in order to supply a gas to the injector 110. The gas supply system 120 has a gas pipe 121 made of metal, e.g., stainless steel, in communication with the injector 110. In addition, a flow rate controller 123 such as a mass flow controller, and an opening/closing valve 122 are sequentially installed in the middle of the gas pipe 121 so that a process gas can be supplied, while controlling a flow rate thereof. Any other process gas necessary for processing the wafer W is also supplied through the gas supply system 120 and the manifold 90 having the same configuration.

A peripheral portion of the manifold 90 in the lower end portion of the process vessel 10 is supported by a base plate 130 made of, for example, stainless steel. The weight of the process vessel 10 is supported by the base plate 130. A lower side of the base plate 130 serves as a wafer transfer chamber having a wafer transferring mechanism (not shown) and is substantially under a nitrogen gas atmosphere at atmospheric pressure. Furthermore, an upper side of the base plate 130 is under an atmosphere of clean air of a clean room.

### (Gas Introduction Mechanism)

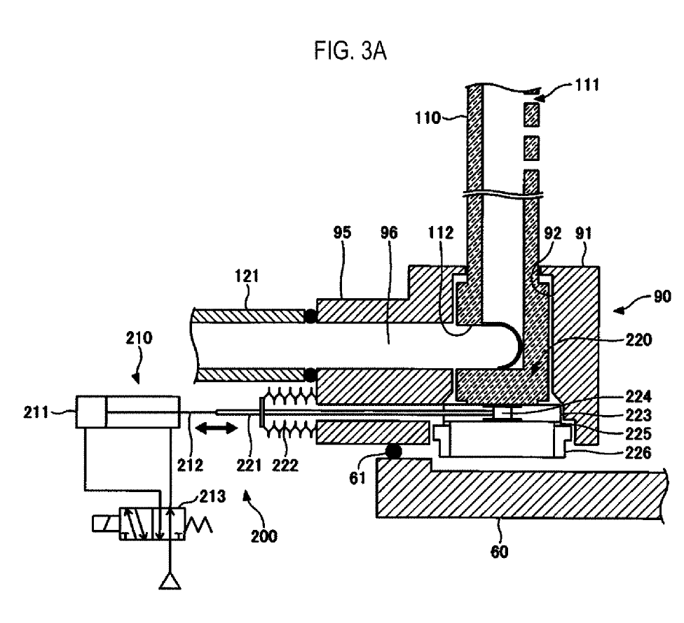

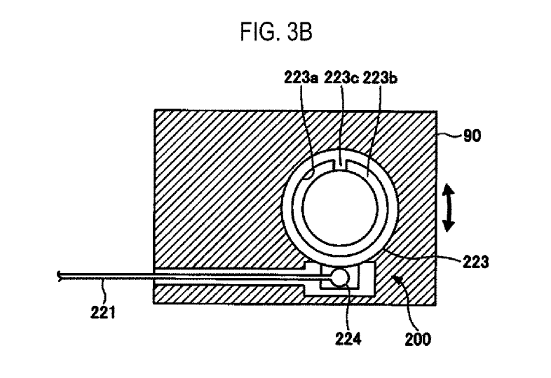

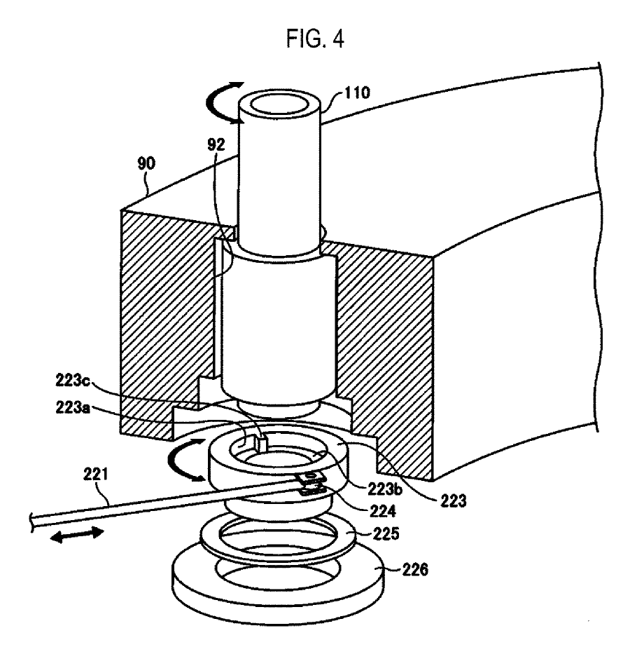

Next, a gas introduction mechanism of the processing apparatus according to one embodiment of the present disclosure will be described. FIGS. 3A and 3B are views illustrating a gas introduction mechanism of the processing apparatus of FIG. 1. FIG. 4 is an exploded perspective view illustrating an internal structure of the gas introduction mechanism of FIGS. 3A and 3B.

As illustrated in FIGS. 3 and 4, the gas introduction mechanism has the manifold 90, the injector 110, the rotation mechanism 200, and the gas pipe 121.

The manifold 90 has an injector support part 91 and a gas introduction part 95.

The injector support part 91 is a part extending along an inner wall surface of the process vessel 10 in a vertical direction and supports the injector 110. The injector support part 91 has an insertion hole 92 into which a lower end of the injector 110 can be inserted. The lower end of the injector 110 can be fitted into the insertion hole 92 and supported by the insertion hole 92.

The gas introduction part 95 is a part which protrudes radially outward from the injector support part 91 and is exposed to the outside of the process vessel 10, and has a gas flow passage 96 communicating with the insertion hole 92 and the outside of the process vessel 10 to allow a gas to flow through the gas flow passage 96. The gas pipe 121 is connected to an outer end portion of the gas flow passage 96 so that gas from outside can be supplied.

The injector 110 is inserted into the insertion hole 92 of the injector support part 91 and entirely extends linearly along the inner wall surface of the process vessel 10, and has an opening 112 communicating with the gas flow passage 96 at a position inserted into the insertion hole 92. The opening 112 has a substantially oval shape with, for example, a longer axis in a horizontal direction and a shorter axis in a vertical direction. Thus, even when the injector 110 rotates, gas is effectively supplied from the gas flow passage 96 to the injector 110.

The manifold 90 is made of, for example, metal. It is desirable that the process vessel 10 and the components constituting the process vessel 10 be basically made of quartz from the view point of preventing metal contamination, but portions having a complicated shape or including a coupling such as a screw or the like may not be made of metal. The manifold 90 of the processing apparatus according to one embodiment of the present disclosure is also made of metal, in which the injector 110 has a bar shape, rather than an L shape. In addition, a gas flow passage 96 is formed to horizontally extend within the gas introduction part 95 of the manifold 90, and an opening 112 communicating with the gas flow passage 96 is formed in the injector 110, eliminating a thick horizontal portion in the injector 110. Thus, since the gas introduction part 95 of the manifold 90 does not need to accommodate a thick horizontal portion of the injector 110, the gas introduction part 95 of the manifold 90 may be reduced in thickness and lowered in height, reducing metal contamination. The metal forming the manifold 90 may also be a corrosion-resistant metal material such as stainless steel, aluminum, hastelloy or the like.

The rotation mechanism 200 may be connected to the lower end portion of the injector 110 and rotate the injector 110 about its longitudinal direction as a central axis. Specifically, the rotation mechanism 200 has an air cylinder 210 and a link mechanism 220, thereby transforming a linear movement (reciprocal movement) generated by the air cylinder 210 into a rotational movement by the link mechanism 220 and transferring the rotational movement to the injector 110.

The air cylinder 210 has a cylinder part 211, a rod part 212, and an electromagnetic valve 213. A portion of the rod part 212 is accommodated in the cylinder part 211. As air controlled by the electromagnetic valve 213 is supplied to the cylinder part 211, the rod part 212 reciprocates in an axial direction (a horizontal direction in FIGS. 3A and 3B) of the cylinder part 211 and the rod part 212. A hydraulic cylinder may also be used instead of the air cylinder 210.

The link mechanism 220 has a link bar 221, a bellows 222, a retainer 223, a link part 224, a washer 225, and a retaining bolt 226.

The link bar 221 has a bar shape and is inserted into the manifold 90 in a state in which air-tightness is maintained by the bellows 222. One end of the link bar 221 is connected to the rod part 212 of the air cylinder 210. Thus, as the rod part 212 reciprocates in the axial direction of the cylinder part 211 and the rod part 212, the link bar 221 reciprocates together with the rod part 212 in the axial direction (the axial direction of the link bar 221) of the cylinder part 211 and the rod part 212. A magnetic fluid seal may also be used instead of the bellows 222.

The retainer 223 is connected to the link bar 221 via the link part 224. Thus, when the link bar 221 reciprocates in its axial direction, the retainer 223 rotates in a leftward direction or rightward direction (a direction indicated by the arrow in FIG. 3B). Specifically, as the link bar 221 moves in the rightward direction, the retainer 223 rotates in the leftward direction, and as the link bar 221 moves in the leftward direction, the retainer 223 rotates in the rightward direction. As illustrated in FIG. 4, an opening 223a is formed in the retainer 223. In the opening 223a, a step portion 223b is formed in a circumferential direction such that the diameter of the opening is reduced stepwise from an upper surface side of the retainer 223 toward a lower surface side thereof. A protrusion 223c is formed on an upper surface of the step portion 223b, and a recess (not shown) formed in the lower end portion of the injector 110 can be engaged with the protrusion 223c. Thus, the retainer 223 retains the injector 110 such that the injector 110 cannot rotate in the circumferential direction relative to the retainer 223. Furthermore, when the retainer 223 rotates, the injector 110 integrally rotates with the retainer 223. The retainer 223 is also rotatably held by the retaining bolt 226 through the washer 225.

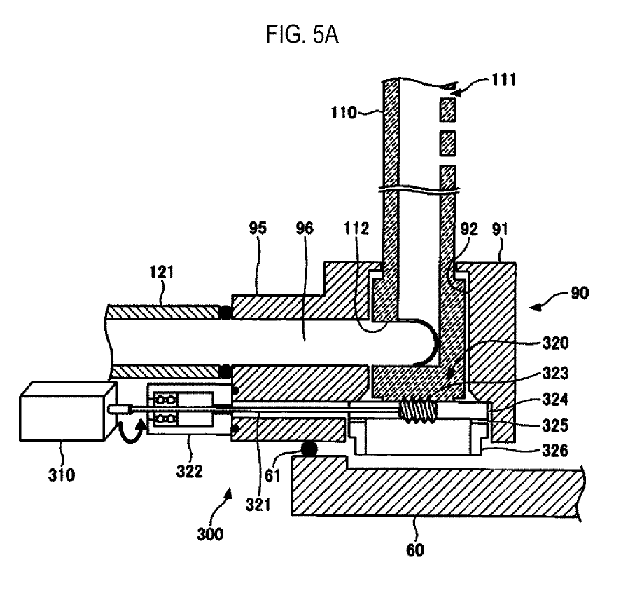

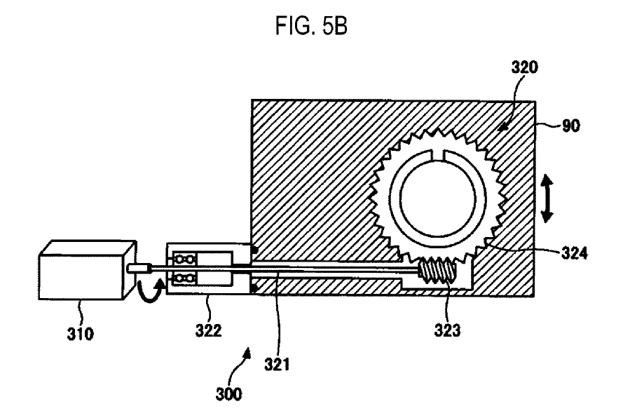

Next, another example of the gas introduction mechanism will be described with reference to FIGS. 5A and 5B. FIGS. 5A and 5B are views illustrating the gas introduction mechanism of the processing apparatus of FIG. 1.

The gas introduction mechanism illustrated in FIGS. 5A and 5B is different from the gas introduction mechanism illustrated in FIG. 4, in that the injector 110 is rotated by a rotation mechanism 300 having a motor 310 and a worm gear mechanism 320. Furthermore, other components are the same as those of the gas introduction mechanism illustrated in FIG. 4. Hereinafter, descriptions of the same components as those of the gas introduction mechanism illustrated in FIG. 4 may be omitted.

As illustrated in FIGS. 5A and 5B, the rotation mechanism 300 is connected to the lower end portion of the injector 110, and rotates the injector 110 about its longitudinal direction as a central axis. Specifically, the rotation mechanism 300 includes the motor 310 and the worm gear mechanism 320, and the rotational movement generated by the motor 310 is transformed in the rotational direction and the rotational speed by the worm gear mechanism 320 and is transferred to the injector 110.

The motor 310 is, for example, a direct current (DC) motor.

The worm gear mechanism 320 includes a rotary shaft 321, a magnetic fluid seal part 322, a worm 323, a worm wheel 324, a washer 325, and a retaining bolt 326.

The rotary shaft 321 has a bar shape and is inserted into the manifold 90 in a state in which air-tightness is maintained by the magnetic fluid seal part 322. One end of the rotary shaft 321 is connected to the motor 310. Thus, the rotary shaft 321 rotates as the motor 310 operates. A bellows may also be used instead of the magnetic fluid seal part 322.

The worm 323 is fixed to a leading end of the rotary shaft 321. Thus, when the rotary shaft 321 rotates, the worm 323 integrally rotates with the rotary shaft 321.

The worm wheel 324 engages with the worm 323 and is configured to be rotatable in forward and reverse directions. Thus, when the worm 323 rotates, the worm wheel 324 rotates in a leftward direction or a rightward direction (a direction indicated by the arrow in FIG. 5B) corresponding to the rotational direction of the worm 323. The worm wheel 324 retains the injector 110 so that the injector 110 cannot rotate in a circumferential direction relative to the worm wheel 324. Thus, when the worm wheel 324 rotates, the injector 110 integrally rotates with the worm wheel 324. Furthermore, the worm wheel 324 is rotatably held by the retaining bolt 326 through the washer 325.

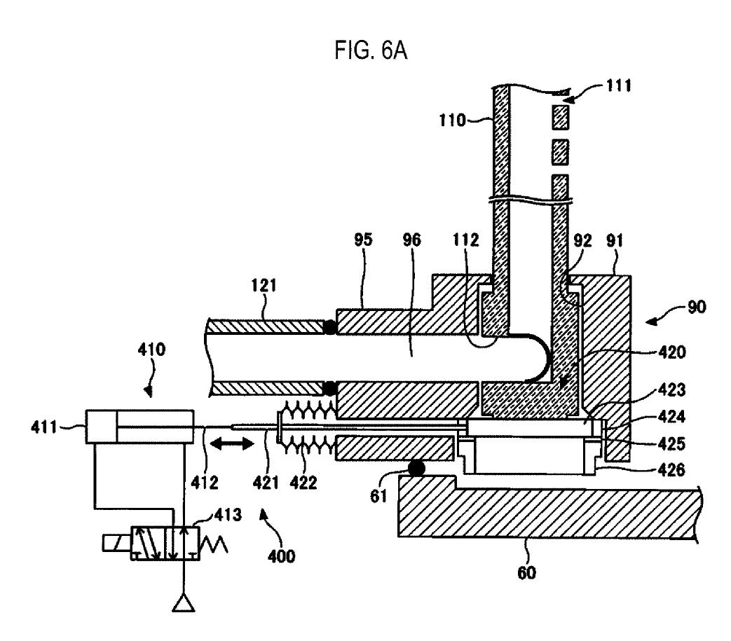

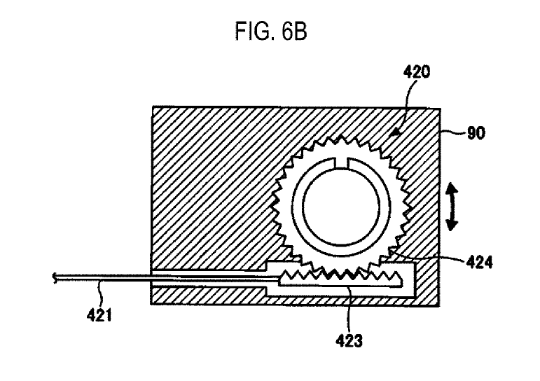

Next, another example of the gas introduction mechanism will be described with reference to FIGS. 6A and 6B. FIGS. 6A and 6B are views illustrating the gas introduction mechanism of the processing apparatus of FIG. 1.

The gas introduction mechanism illustrated in FIGS. 6A and 6B is different from the gas introduction mechanism illustrated in FIG. 4, in that the injector 110 is rotated by a rotation mechanism 400 having an air cylinder 410 and a rack and pinion mechanism 420. Furthermore, other components are the same as those of the gas introduction mechanism illustrated in FIG. 4. Hereinafter, descriptions of the same components as those of the gas introduction mechanism illustrated in FIG. 4 may be omitted.

As illustrated in FIGS. 6A and 6B, the rotation mechanism 400 is connected to the lower end portion of the injector 110, and rotates the injector 110 about its longitudinal direction as a central axis. Specifically, the rotation mechanism 400 includes the air cylinder 410 and the rack and pinion mechanism 420, and the linear movement generated by the air cylinder 410 is transformed into the rotational movement by the rack and pinion mechanism 420, and transferred to the injector 110.

The air cylinder 410 has a cylinder part 411, a rod part 412, and an electromagnetic valve 413. A portion of the rod part 412 is accommodated in the cylinder part 411. The air controlled by the electromagnetic valve 413 is supplied to the cylinder part 411so that the rod part 412 reciprocates in an axial direction (a horizontal direction in FIGS. 6A and 6B) of the cylinder part 411 and the rod part 412. A hydraulic cylinder may also be used instead of the air cylinder 410.

The rack and pinion mechanism 420 has a drive shaft 421, a bellows 422, a rack 423, a pinion 424, a washer 425, and a retaining bolt 426.

The drive shaft 421 has a rod shape and is inserted into the manifold 90 in a state in which air-tightness is maintained by the bellows 422. One end of the drive shaft 421 is connected to the rod part 412 of the air cylinder 410. Thus, as the rod part 412 reciprocates in the axial direction of the cylinder part 411 and the rod part 412, the drive shaft 421reciprocates together with the rod part 412 in the axial direction (the axial direction of the drive shaft 421) of the cylinder part 411 and the rod part 412. A magnetic fluid seal may also be used instead of the bellows 422.

The rack 423 is fixed to a leading end of the drive shaft 421. Thus, when the drive shaft 421 reciprocates, the rack 423 integrally reciprocates with the drive shaft 421. The rack 423 may also be integrally formed with the drive shaft 421.

The pinion 424 engages with the rack 423 and is configured to be rotatable in forward and reverse directions. Thus, when the rack 423 reciprocates, the pinion 424 rotates in a leftward direction or a rightward direction (a direction indicated by the arrow in FIG. 6B) corresponding to the reciprocating movement of the rack 423. The pinion 424 retains the injector 110 such that the injector 110 cannot rotate in a circumferential direction relative to the pinion 424. Thus, when the pinion 424 rotates, the injector 110 integrally rotates with the pinion 424. Furthermore, the pinion 424 is rotatably held by the retaining bolt 426 via the washer 425.

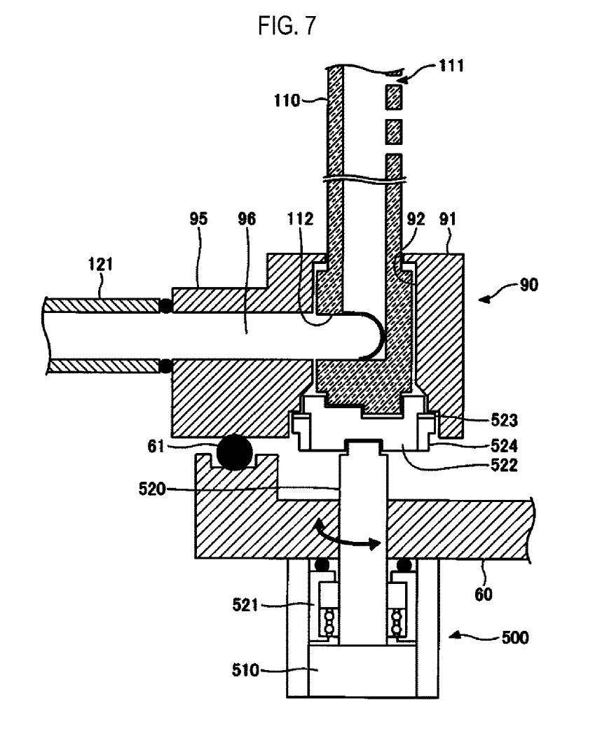

Next, another example of the gas introduction mechanism will be described with reference to FIG. 7. FIG. 7 is a view illustrating the gas introduction mechanism of the processing apparatus of FIG. 1.

The gas introduction mechanism illustrated in FIG. 7 is different from the gas introduction mechanism illustrated in FIG. 4, in that the injector 110 is rotated by a rotation mechanism 500 having a motor 510 and a rotary shaft 520. Furthermore, other components are the same as those of the gas introduction mechanism illustrated in FIG. 4. Hereinafter, descriptions of the same components as those of the gas introduction mechanism illustrated in FIG. 4 may be omitted.

As illustrated in FIG. 7, the rotation mechanism 500 is connected to the lower end portion of the injector 110, and rotates the injector 110 about its longitudinal direction as a central axis. Specifically, the rotation mechanism 500 includes the motor 510 and the rotary shaft 520, and the rotational movement generated by the motor 510 is transmitted to the injector 110 by the rotary shaft 520.

The motor 510 is, for example, a DC motor.

The rotary shaft 520 has a bar shape, and penetrates the lid 60 from the lower side of the lid 60 and is connected to the lower end portion of the injector 110 through a connection member 522 in a state in which air-tightness is maintained by the magnetic fluid seal part 521. Thus, the rotary shaft 520 rotates as the motor 510 operates. A bellows may also be used instead of the magnetic fluid seal part 521. Furthermore, the connection member 522 is rotatably held by the retaining bolt 524 through the washer 523.

### EXAMPLES

Next, an in-plane distribution of film thickness of a film formed on a surface of a wafer W when the direction (discharge angle) of a gas discharged from the gas hole 111 of the injector 110 is changed will be described.

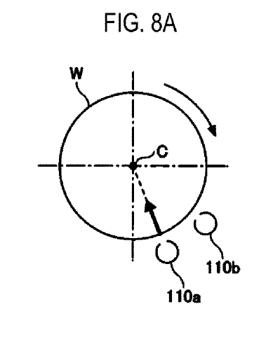

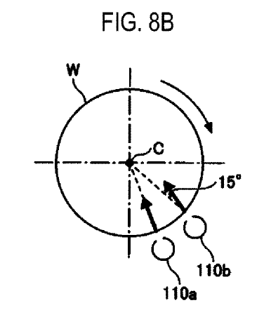

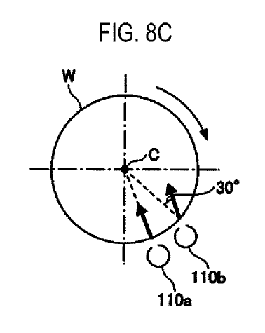

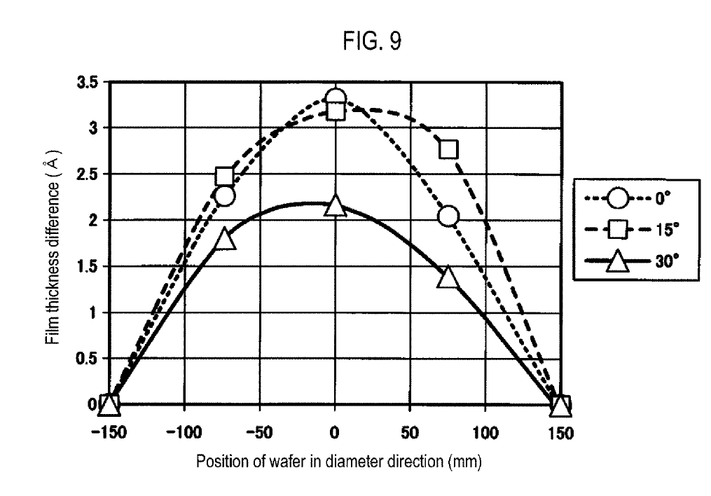

FIGS. 8A to 8C are views illustrating a direction of a gas discharged from the gas hole of the injector. FIG. 9 is a diagram illustrating an in-plane distribution in film thickness of a film formed on the wafer. In FIG. 9, the horizontal axis represents positions (mm) including the center of the wafer W in a diameter direction and the vertical axis represents a difference (A) from a minimum film thickness of the wafer W in the diameter direction (hereinafter, referred to as a “film thickness difference”). Furthermore, the circular indication represents a case where the discharge angle is 0°, the square indication represents a case where the discharge angle is 15°, and the triangular indication represents a case where the discharge angle is 30°.

As illustrated in FIG. 9, it can be seen that the distribution of the film thickness of a film formed on the wafer W is changed by changing the angle of a gas hole 111b formed in a second injector 110b. Specifically, when the discharge angle is 0° and 15°, the film thickness difference at a central position (0 mm) of the wafer W is 3 to 3.5 Å, whereas when the discharge angle is 30°, the film thickness difference at the central position of the wafer W is about 2 Å. That is, it can be seen that when the discharge angle is 30°, the film thickness distribution in the plane of the wafer W is small, compared with the case where the discharge angles are 0° and 15°.

Furthermore, the “discharge angle 0°” refers to a condition in which a dichlorosilane (DCS) gas is discharged in a state in which the discharge angle of the gas discharged from a gas hole 111a of a first injector 110a is set to an angle orienting toward the rotation center C of the wafer W, as illustrated in FIG. 8A. At this time, a gas is not supplied from the gas hole 111b of the second injector 110b.

The “discharge angle 15°” refers to a condition in which a DCS gas is discharged in a state in which the discharge angle of the gas discharged from the gas hole 111a of the first injector 110a is set to an angle oriented toward the rotation center C of the wafer W, and the DCS gas is discharged in a state in which the discharge angle of the gas discharged from the gas hole 111b of the second injector 110b is rotated by 15° in a rightward direction from an angle oriented toward the rotation center C of the wafer W, as illustrated in FIG. 8B.

The “discharge angle 30°” refers to a condition in which a DCS gas is discharged in a state in which the discharge angle of the gas discharged from the gas hole 111a of the first injector 110a is set to an angle oriented toward the rotation center C of the wafer W, and the DCS gas is discharged in a state in which the discharge angle of the gas discharged from the gas hole 111b of the second injector 110b is rotated by 30° in a rightward direction from an angle oriented toward the rotation center C of the wafer W, as illustrated in FIG. 8C.

As described above, it is possible to control the in-plane distribution of thickness of the film formed on the surface of the wafer W by changing the discharge angle of the gas.

While the embodiments for carrying out the present disclosure have been described above, the present disclosure is not limited by the contents of the embodiments and different and various modifications and improvements can be available within the scope of the present disclosure.

In the aforementioned embodiment, there has been described a case where one or two injectors 110 are used as an example. However, the present disclosure is not limited thereto and three or more injectors 110 may be installed. In addition, when there is a plurality of injectors 110, it is sufficient that at least one of the plurality of injectors 110 is rotatably installed, and the other injectors 110 may be fixed to the manifold. Furthermore, all of the plurality of injectors 110 may be rotatably installed. Moreover, the discharge range of the injector 110 with respect to the loading direction of the wafer W is not limited, and the discharge angle of the gas in the plurality of injectors 110 may be changed for each zone.

According to the present disclosure in some embodiments, it is possible to control an in-plane distribution in a process performed on a substrate by the disclosed substrate processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas introduction mechanism installed in a process vessel to perform a predetermined process on a substrate in the process vessel using a predetermined gas, comprising:
a manifold disposed in a lower end portion of the process vessel, and having an injector support part extending vertically along an inner wall surface of the process vessel and having an insertion hole, and a gas introduction part having a gas flow passage which protrudes outward from the injector support part and which communicates with the insertion hole and an outside of the process vessel so that a gas can flow through the insertion hole and the outside of the process vessel;
an injector inserted and fitted into the insertion hole to be supported by the insertion hole, and extending linearly entirely within the injector along the inner wall surface and has an opening communicating with the gas flow passage at a position inserted into the insertion hole; and
a rotation mechanism connected to a lower end portion of the injector to rotate the injector.

2. The gas introduction mechanism of claim 1, wherein the rotation mechanism comprises:
a link mechanism connected to the lower end portion of the injector; and
a cylinder connected to the link mechanism to drive the link mechanism.

3. The gas introduction mechanism of claim 1, wherein the rotation mechanism comprises:
a worm gear mechanism connected to the lower end portion of the injector; and
a motor connected to the worm gear mechanism to drive the worm gear mechanism.

4. The gas introduction mechanism of claim 1, wherein the rotation mechanism comprises:
a rack and pinion connected to the lower end portion of the injector; and
a cylinder connected to the rack and pinion to drive the rack and pinion.

5. The gas introduction mechanism of claim 1, wherein the rotation mechanism comprises:
a rotary shaft connected to the lower end portion of the injector; and
a motor connected to the rotary shaft to rotate the rotary shaft.

6. The gas introduction mechanism of claim 1, wherein a plurality of gas holes are formed in the injector in a longitudinal direction.

7. The gas introduction mechanism of claim 1, wherein the process vessel and the injector are made of quartz, and
the manifold is made of metal.

8. A processing apparatus, comprising:
a process vessel;
a manifold disposed in a lower end portion of the process vessel, and having an injector support part extending vertically along an inner wall surface of the process vessel and having an insertion hole, and a gas introduction part having a gas flow passage which protrudes outward from the injector support part and which communicates with the insertion hole and an outside of the process vessel so that a gas can flow through the insertion hole and the outside of the process vessel;
an injector inserted and fitted into the insertion hole to be supported by the insertion hole, and extending linearly entirely within the injector along the inner wall surface and has an opening communicating with the gas flow passage at a position inserted into the insertion hole; and
a rotation mechanism connected to a lower end portion of the injector to rotate the injector.

9. The apparatus of claim 8, wherein the process vessel has a substantially cylindrical shape to accommodate a substrate support which can support a plurality of substrates in a vertically spaced state.
